(19) United States
(12) Patent Application Publication
(10) Pub. No.: US 2008/0293193 A1
(43) Pub. Date: Nov. 27, 2008

(54) USE OF LOW TEMPERATURE ANNEAL TO PROVIDE LOW DEFECT GATE FULL SILICIDATION

(75) Inventors: Mark Visokay, Richardson, TX (US); Jorge Adrian Kittl, Waterloo (BE)

Correspondence Address: TEXAS INSTRUMENTS INCORPORATED, P O BOX 655474, M/S 3999, DALLAS, TX, 75265, US

(73) Assignee: Texas Instruments Inc., Dallas, TX (US)

(21) Appl. No.: 11/752,420

(22) Filed: May 23, 2007

(51) Int. Cl. H01L 21/336

(52) U.S. Cl. 438/199; 438/308; 257/E21.438

(57) ABSTRACT

Provided is a method for manufacturing a semiconductor device that includes forming a gate structure over a substrate, wherein the gate structure includes a gate dielectric and a gate electrode. The method further includes forming a metal layer over the gate electrode, and forming a fully silicided gate electrode using the metal layer. The fully silicided gate electrode may be formed by subjecting the gate electrode to a first anneal in a presence of the metal layer to form a silicided gate electrode, wherein a maximum temperature of the first anneal does not exceed about 340° C. The fully silicided gate electrode may further be formed by removing any unreacted portions of the metal layer after the first anneal, and subjecting the silicided gate electrode to a second anneal to form the fully silicided gate electrode subsequent to the removing. A maximum temperature of the second anneal exceeds about 400° C.

### TECHNICAL FIELD OF THE INVENTION

The invention is directed, in general, to the silicidation of gates and, more specifically, to the use of a low temperature anneal to provide low defect gate full silicidation.

### BACKGROUND OF THE INVENTION

Metal gate electrodes are currently being investigated to replace polysilicon gate electrodes in today's ever shrinking and changing transistor devices. One of the principal reasons the industry is investigating replacing the polysilicon gate electrodes with metal gate electrodes is in order to solve problems of poly-depletion. Traditionally, a polysilicon gate electrode with an overlying silicide was used for the gate electrodes in metal oxide semiconductor (MOS) devices. However, as device feature size continues to shrink, poly depletion becomes a serious issue when using polysilicon gate electrodes.

Accordingly, metal gates have been proposed. However, in order to optimize the performance of CMOS devices, the metal gates need dual tunable work functions. For instance, the metal gates need tunable work functions for NMOS and PMOS devices similar to present polysilicon gate technology, requiring the work functions of metal gates to range from 4.1˜4.4 eV for NMOS and 4.8˜5.1 eV for PMOS (see, B. Cheng, B. Maiti, S. Samayedam, J. Grant, B. Taylor, P. Tobin, J. Mogab, IEEE Intl. SOI Conf. Proc., pp. 91-92, 2001).

Recently, silicided metal gates have been investigated based on the extension of existing self-aligned silicide (SALICIDE) technology. In this approach, polysilicon is deposited over the gate dielectric. A metal is deposited over the polysilicon and reacted to completely consume the polysilicon resulting in a fully silicided metal gate, rather than a deposited metal gate. The silicided metal gate provides a metal gate with the least perturbation to the conventional process, and avoids contamination issues.

Nevertheless, one problem associated with this technology is the ability (or inability) to completely react all of the polysilicon in the gate electrode with the silicidation metal. For example, if the anneal used to form the silicide is too mild the gate electrodes will not fully react; however, if the anneal used to form the silicide is too aggressive the silicidation metal can penetrate into the channel, which is catastrophic to the device.

Accordingly, what is needed is a method for manufacturing silicided metal gate structures that does not experience these and other drawbacks of the prior art methods.

### SUMMARY OF THE INVENTION

To address the above-discussed deficiencies of the prior art, the disclosure provides a method for manufacturing a semiconductor device. The method for manufacturing the semiconductor device, in one embodiment, includes forming a gate structure over a substrate, wherein the gate structure includes a gate dielectric and a gate electrode. The method further includes forming a metal layer over the gate electrode, and forming a fully silicided gate electrode using the metal layer. The fully silicided gate electrode may be formed by subjecting the gate electrode to a first anneal in a presence of the metal layer to form a silicided gate electrode, wherein a maximum temperature of the first anneal does not exceed about 340° C. The fully silicided gate electrode may further be formed by removing any unreacted portions of the metal layer after the first anneal, and subjecting the silicided gate electrode to a second anneal to form the fully silicided gate electrode subsequent to the removing. A maximum temperature of the second anneal, in this embodiment, exceeds about 400° C.

The method for manufacturing the semiconductor device, in another embodiment, includes forming a gate structure over a substrate, wherein the gate structure includes a gate dielectric and a gate electrode. The method further includes forming a metal silicide layer over the gate electrode, and annealing the gate electrode in the presence of the metal silicide layer to form a fully silicided gate electrode, wherein a maximum temperature of the annealing does not exceed about 340° C.

In an alternative embodiment, the method for manufacturing the semiconductor device includes: 1) forming a substrate having a p-type metal oxide semiconductor (PMOS) device region and n-type metal oxide semiconductor (NMOS) device region; 2) forming a first gate structure having a first gate dielectric and a first gate electrode, and a second gate structure having a second gate dielectric and a second gate electrode are formed over the PMOS device region and the NMOS device region, respectively; 3) forming first source/drain regions on opposing sides of the first gate structure and second source/drain regions on opposing sides of the second gate structure; 4) forming a metal layer in contact with the first gate electrode and the second gate electrode; and 5) annealing the first gate electrode and the second gate electrode in the presence of the metal layer to form a first silicided gate electrode and a second silicided gate electrode, wherein a maximum temperature of the annealing does not exceed about 340° C.

In yet another embodiment, the method for manufacturing the semiconductor device includes selecting a maximum silicidation temperature based upon a desire to exclude a predetermined silicidation transient phase of a gate electrode material. This embodiment further includes forming a gate structure over a substrate, wherein the gate structure includes a gate dielectric and a gate electrode including the gate electrode material, and forming a metal layer over the gate electrode. This method additionally includes annealing the gate electrode using the selected maximum silicidation temperature in the presence of the metal layer to form a silicided gate electrode.

### BRIEF DESCRIPTION OF THE DRAWINGS

For a more complete understanding of the disclosure, reference is now made to the following descriptions taken in conjunction with the accompanying drawings, in which:

FIGS. 1-12 illustrate detailed steps of one example embodiment for manufacturing a semiconductor device in accordance with this disclosure; and

FIG. 13 illustrates an integrated circuit (IC) having been manufactured using one embodiment of the disclosure.

### DETAILED DESCRIPTION

The present disclosure is based, at least in part, on the acknowledgement that certain transient phases that may exist during a typical silicidation process are particularly problematic. The phrase “transient phases”, as used throughout this disclosure, means material phases of the metal silicide that may exist during the process of siliciding a polysilicon material but that do not exist after the process is complete. More specifically, the present disclosure acknowledges that certain ones of these transient phases result in transient stress in the material being silicided. The phrase “transient stress”, as used throughout this disclosure, means stress that exists during the process of siliciding a polysilicon material but that does not exist after the process is complete. Moreover, the present disclosure acknowledges that the transient stresses may, in certain instances, be the cause of metal punch through into the channel region of semiconductor devices, and thus ultimate device failure.

Based upon these acknowledgements, as well as substantial experimentation, the present disclosure recognizes that the selection and use of low temperature anneals to silicidize the gate electrode material, reduces or eliminates the formation of the transient phases that tend to cause unwanted transient stress. For example, the present disclosure recognizes that the use of formation anneals using maximum temperatures below about 340° C. may reduce or eliminate the formation of certain transient phases while activating the silicidation process. In one specific embodiment, the present disclosure recognizes that maximum anneal temperatures below about 300° C. may reduce, or even prevent, the formation of Ni₃₁Si₁₂ (e.g., also referred to as Ni₅Si₂). Other low temperatures, however, might also be used to reduce or prevent the formation of the Ni₃₁Si₁₂, as well as other undesirable transient phases. Nevertheless, the use of such lower temperatures, and thus generally longer anneal times, goes against the desires of the industry to increase throughput. Accordingly, the use of these lower temperatures is counterintuitive to the traditional desires of the industry.

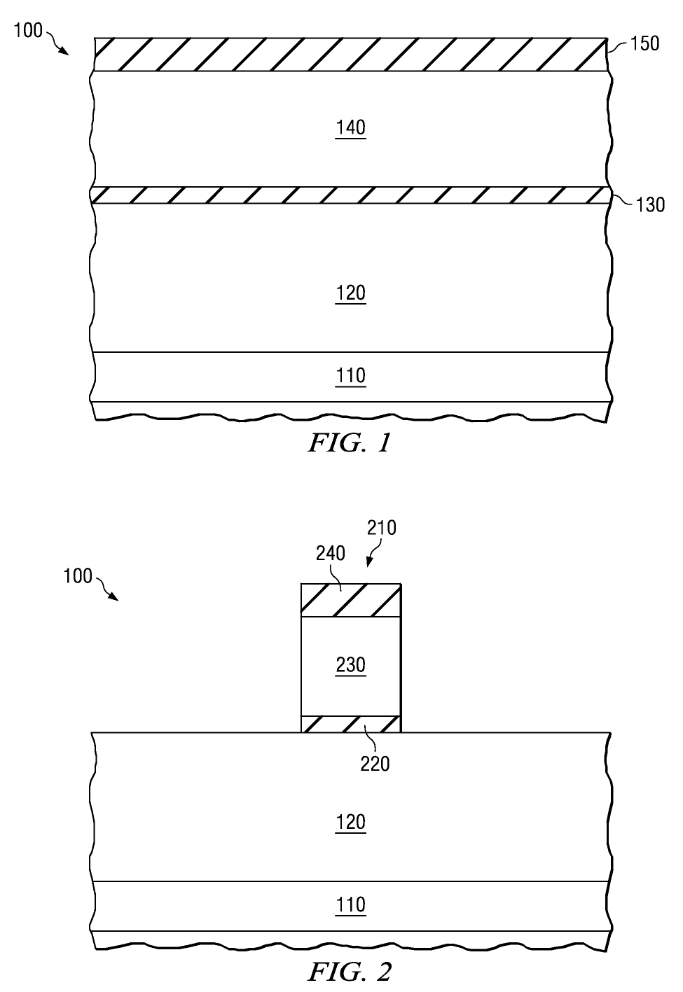

FIGS. 1-12 illustrate detailed steps of one example embodiment for manufacturing a semiconductor device in accordance with this disclosure. FIG. 1 illustrates a semiconductor device 100 at an initial stage of manufacture. The device 100 includes a substrate 110. The substrate 110 may, in one embodiment, be any layer located in the device 100, including a wafer itself or a layer located above the wafer (e.g., epitaxial layer). In the embodiment illustrated in FIG. 1, the substrate 110 is a p-type substrate; however, one skilled in the art understands that the substrate 110 could be an n-type substrate without departing from the disclosure. In such an embodiment, certain ones of the dopant types described throughout the remainder of this document might be reversed. For clarity, no further reference to this opposite scheme will be discussed.

Located within the substrate 110 in the embodiment shown in FIG. 1 is a well region 120. The dopant type for the well region 120 would typically depend on whether the device 100 is a PMOS device or NMOS device. In those embodiments wherein the device 100 is a PMOS device, the well region 120 would include an n-type dopant. In those embodiments wherein the device 100 is an NMOS device, the well region 120 would include a p-type dopant. Those skilled in the art understand that in certain circumstances where the p-type substrate 110 dopant concentration is high enough, and the device 100 comprises an NMOS device, the well region 120 may be excluded. In those embodiments wherein the well region 120 exists, it would likely be ion implanted using a dopant dose ranging from about 1E13 atoms/cm² to about 1E14 atoms/cm² and at an energy ranging from about 100 keV to about 500 keV. This results in the well region 120 having a peak dopant concentration ranging from about 5E17 atoms/cm³ to about 1E19 atoms/cm³.

Located over the substrate 110 in the embodiment of FIG. 1 is a layer of gate dielectric material 130 and a layer of gate electrode material 140. The layer of gate dielectric material 130 may comprise a number of different materials and stay within the scope of the present invention. For example, the layer of gate dielectric material 130 may comprise silicon dioxide in one embodiment. In another embodiment, the layer of gate dielectric material 130 can be any one of a number of high-K dielectric materials and be within the scope of this disclosure. Such materials include a variety of hafnium and zirconium silicates and their various oxides. For example, in one embodiment the high-k dielectric material might comprise HfSiO, however in other embodiments the high-k dielectric material might comprise HfO₂, HfSiON, HfAlO or HfLaO.

The layer of gate dielectric material 130 may additionally be formed to varying thicknesses. For example, in the embodiment wherein the layer of gate dielectric material 130 comprises silicon dioxide, it might have a thickness ranging from about 0.5 nm to about 5 nm, and more specifically a thickness ranging from about 1 nm to about 3 nm. In the embodiment wherein the layer of gate dielectric material 130 comprises a high-k material, for example a hafnium based material, it might have a thickness ranging from about 1.5 nm to about 5 nm. Other thicknesses could nonetheless also be used.

Any one of a plurality of manufacturing techniques could be used to form the layer of gate dielectric material 130. For example, the layer of gate dielectric material 130 may be either grown or deposited. Additionally, the growth or deposition steps may require a significant number of different temperatures, pressures, gasses, flow rates, etc. Those skilled in the art understand the skill that may be required to tailor such process conditions.

The layer of gate electrode material 140 should comprise a material capable of being silicided. Accordingly, in one embodiment the layer of gate electrode material 140 comprises standard polysilicon. In an alternative embodiment, however, the layer of gate electrode material 140, or at least a portion thereof, comprises amorphous polysilicon. The amorphous polysilicon embodiment may be particularly useful when a substantially planar upper surface of the layer of gate electrode material 140 is desired. Nevertheless, this amorphous polysilicon embodiment will be discussed no further.

The deposition conditions for the layer of gate electrode material 140 may vary. However, if the layer of gate electrode material 140 were to comprise standard polysilicon, such as the instance in FIG. 1, the layer of gate electrode material 140 could be deposited using a pressure ranging from about 100 torr to about 300 torr and a temperature ranging from about 620° C. to about 700° C. Additionally, a SiH₄ or Si₂H₆ gas flow ranging from about 50 sccm to about 150 sccm might be used. Other deposition conditions different from those disclosed could nonetheless also be used. The layer of gate electrode material 140 desirably has a thickness ranging from about 50 nm to about 150 nm, among others.

The device 100 of FIG. 1 further includes a layer of protective material 150 located over the layer of gate electrode material 140. In one embodiment, the layer of protective material 150 is located directly on the layer of gate electrode material 140; however, other embodiments exist wherein one or more layers interpose the two. The layer of protective material 150, which may comprise silicon nitride among other materials, may have a thickness ranging from about 5 nm to about 50 nm. Nevertheless, the layer of protective material 150 should have a thickness sufficient to adequately protect the layer of gate electrode material 140. The layer of protective material 150, in one embodiment, functions as a hardmask layer.

FIG. 2 illustrates the device 100 of FIG. 1 after patterning a gate structure 210 including a gate dielectric 220 and gate electrode 230 using a patterned portion 240 of the layer of protective material 150. In the example embodiment of FIG. 2, the patterned portion 240 is formed using well-known lithography processes. Thereafter, an etch process could be used to define the gate structure 210 using the patterned portion 240. What results is the gate structure 210 including the gate dielectric 220 and gate electrode 230.

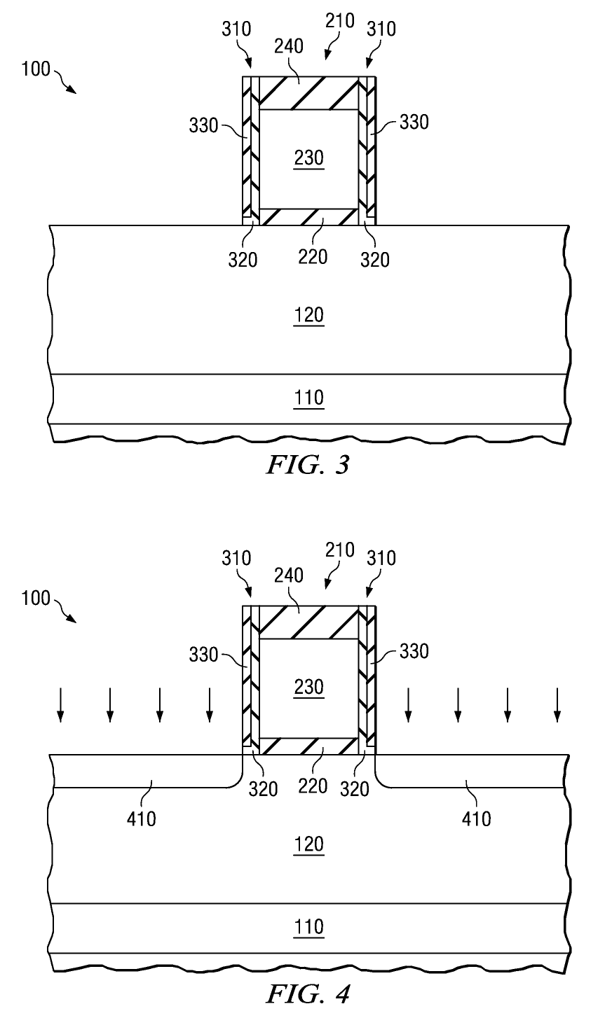

FIG. 3 illustrates the device 100 of FIG. 2 after forming portions of gate sidewall spacers 310. The portions of the gate sidewall spacers 310 shown in FIG. 3 include an oxide layer 320 and an offset nitride spacer 330. Nevertheless, other layers may be used for the gate sidewall spacers 310. In the embodiment of FIG. 3, the oxide layer 320 and offset nitride spacer 330 were formed using standard processes. However, other non-standard processes could be used.

FIG. 4 illustrates the device 100 of FIG. 3 after the formation of extension implants 410 within the substrate 110. The extension implants 410 may be conventionally formed and generally have a peak dopant concentration ranging from about 1E19 atoms/cm³ to about 2E20 atoms/cm³. As is standard in the industry, the extension implants 410 have a dopant type opposite to that of the well region 120 they are located within. Thus, in the embodiment wherein the device 100 is a PMOS device the extension implants 410 might comprise a p-type dopant, and in the embodiment wherein the device 100 is an NMOS device the extension implants 410 might comprise an n-type dopant.

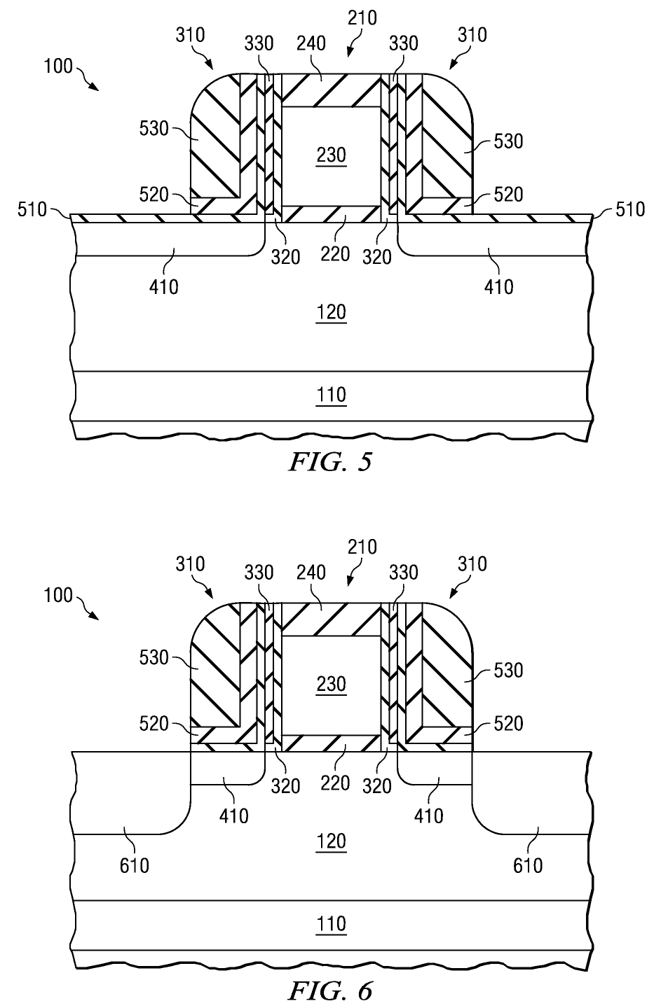

FIG. 5 illustrates the device 100 of FIG. 4 after forming remaining portions of the gate sidewall spacers 310. Particularly, a cap oxide 510, L-shaped nitride spacers 520 and sidewall oxides 530 complete the gate sidewall spacers 310. FIG. 5 indicates that an L-shaped scheme is used to complete the gate sidewall spacers. However, other embodiments exist wherein a single bulk spacer, for example comprising an oxide, completes the gate sidewall spacers. The remaining portions of the gate sidewall spacers 310 may be manufactured using, among others, conventional processes.

FIG. 6 illustrates the device 100 of FIG. 5 after the formation of source/drain implants 610 within the substrate 110. The formation of the source/drain implants 610 may, in one embodiment, be conventional. Generally the source/drain implants 610 have a peak dopant concentration ranging from about 1E18 atoms/cm³ to about 1E21 atoms/cm³. The source/drain implants 610 typically have a dopant type opposite to that of the well region 120 they are located within. Thus, in the embodiment wherein the device 100 is a PMOS device the source/drain implants 610 might comprise a p-type dopant, and in the embodiment wherein the device 100 is an NMOS device the source/drain implants 610 might comprise an n-type dopant.

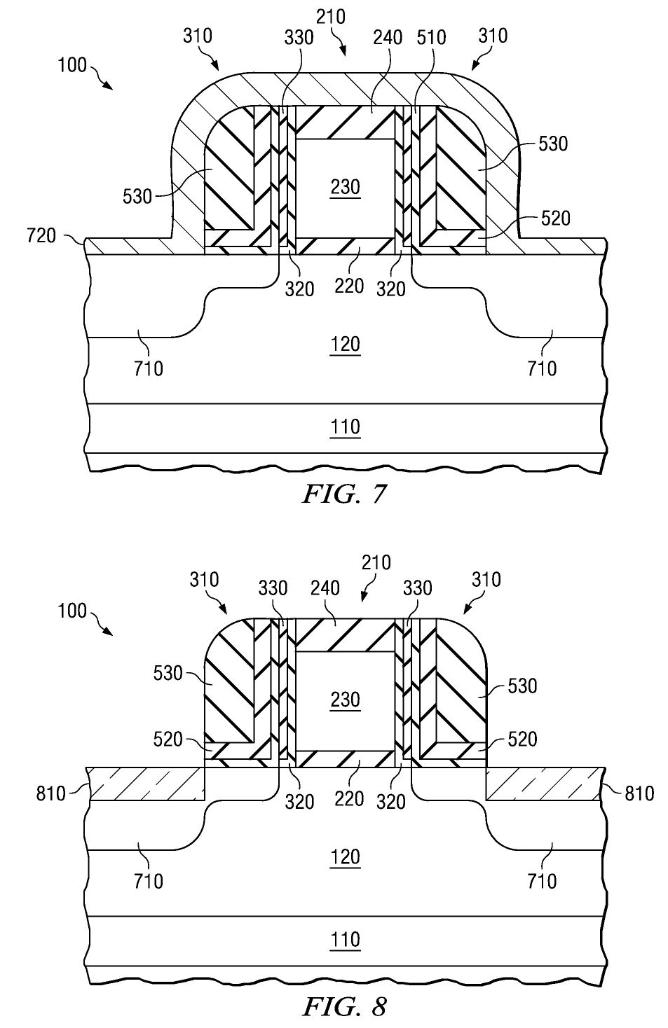

FIG. 7 illustrates the device 100 of FIG. 6 after subjecting it to a source/drain anneal, thereby activating source/drain regions 710. It is believed that a source/drain anneal conducted at a temperature ranging from about 1000° C. to about 1350° C. and a time period ranging from about 1 millisecond to about 5 seconds would be sufficient. It should be noted that other temperatures, times, and processes could be used to activate the source/drain regions 710.

Additionally illustrated in FIG. 7 is the formation of a metal 720 over the exposed portions of the source/drain regions 710 as well as over the gate structure 210. As shown, the metal 720 may cover the entire surface of the device 100. The metal 720 in the embodiment shown in FIG. 7 happens to be a thin cobalt layer, however, other materials that react with silicon to form a silicide could easily be used. For instance, it is known that the metal 720 may also comprise nickel, platinum, titanium, tantalum, molybdenum, tungsten, another similar metal, or any combination thereof while staying within the scope of the present disclosure.

The metal 720 may be formed using a number of different processes, and may be formed to a number of different thicknesses. In one embodiment, the metal 720 is deposited to a thickness ranging from about 3 nm to about 15 nm. Such thicknesses, however, might be used when the metal 720 comprises cobalt. Various other thicknesses could be used if the metal 720 were to comprise one of the different metals disclosed above.

FIG. 8 illustrates the device 100 of FIG. 7 after subjecting it to a first rapid thermal anneal (RTA) and subsequent selective metal strip. This RTA attempts to cause the metal 720 to react with the silicon of the source/drain regions 710 to form silicided source/drain regions 810. In the instance where the metal 720 comprises cobalt, the first RTA causes the cobalt to react with the silicon to form a cobalt silicide.

The first RTA may be conducted using a variety of different temperatures and times. Nonetheless, it is believed that the first RTA, in one embodiment, should be conducted in a rapid thermal processing tool at a temperature ranging from about 350° C. to about 550° C. and a time period ranging from about 10 second to about 100 seconds to accomplish the silicidation, particularly when cobalt is used. The specific temperature and time period are typically based, however, on the ability to form the silicided source/drain regions 810 to a desired depth, as well as the silicide materials selected. A selective wet etch, using for example a mixture of sulfuric acid (H₂SO₄), hydrogen peroxide (H₂O₂) and water (H₂O), may then be used to remove un-reacted metal 720.

Additionally, another optional second RTA step may be used to form a low resistivity phase of the silicide. In the case of using a cobalt silicidation metal, the first RTA forms CoSi, while the optional second RTA forms CoSi₂, which has lower resistivity and is more stable. This optional second RTA step is typically performed using a temperature ranging from about 650° C. to about 800° C. for a time period ranging from about 5 to about 60 seconds.

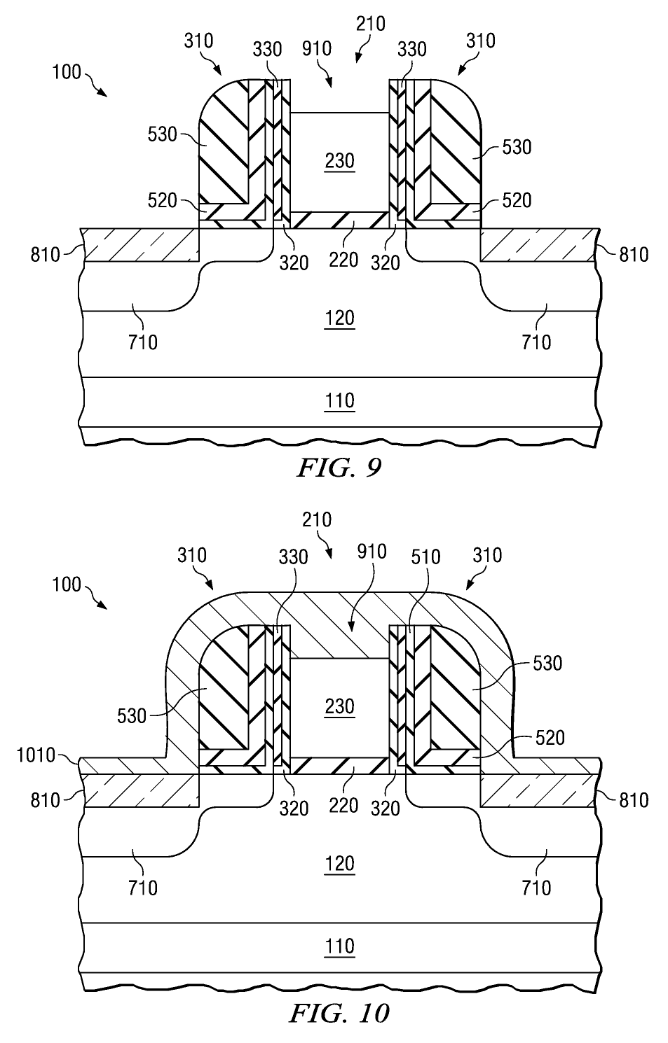

FIG. 9 illustrates the device 100 of FIG. 8 after removing the patterned portion 240 from over the gate electrode 230 to form an opening 910. In one embodiment, the etchant used to remove the patterned portion 240 is highly selective to the gate electrode 230. Accordingly, this etchant does not substantially affect the gate electrode 230. Those skilled in the art appreciate that the specific etch chosen for the patterned portion 240 is highly dependent on the materials for each and the etch selectivities for each.

FIG. 10 illustrates the device 100 of FIG. 9 after depositing a second metal 1010 over the exposed portions of the gate electrode 230, as well as over the remainder of the semiconductor device 100. In this disclosed embodiment, the metal 1010 is formed in contact with the gate electrode 230 and designed to silicidize the gate electrode 230. For example, in the embodiment wherein the second metal 1010 is nickel, the nickel layer would be deposited to a thickness sufficient to silicidize the gate electrode 230. As it takes approximately 1 nm of nickel to silicidize approximately 1.8 nm of polysilicon, the thickness of the metal 1010, in this embodiment, should be at least 56% of the thickness of the gate electrode 230. To be comfortable, however, it is suggested that the thickness of the metal 1010 should be at least 60% of the thickness of the gate electrode 230. Thus, where the thickness of the gate electrode 230 ranges from about 50 nm to about 150 nm, as described above, the thickness of the metal 1010 should range from approximately 30 nm to about 90 nm.

It should also be noted that the metal 1010 might comprise a number of different metals or combinations of metals while staying within the scope of the present disclosure. For example, the metal 1010 may comprise any metal known to react with polysilicon to form a metal silicide. In these embodiments, the thickness of the silicidation metal might be different from that disclosed above.

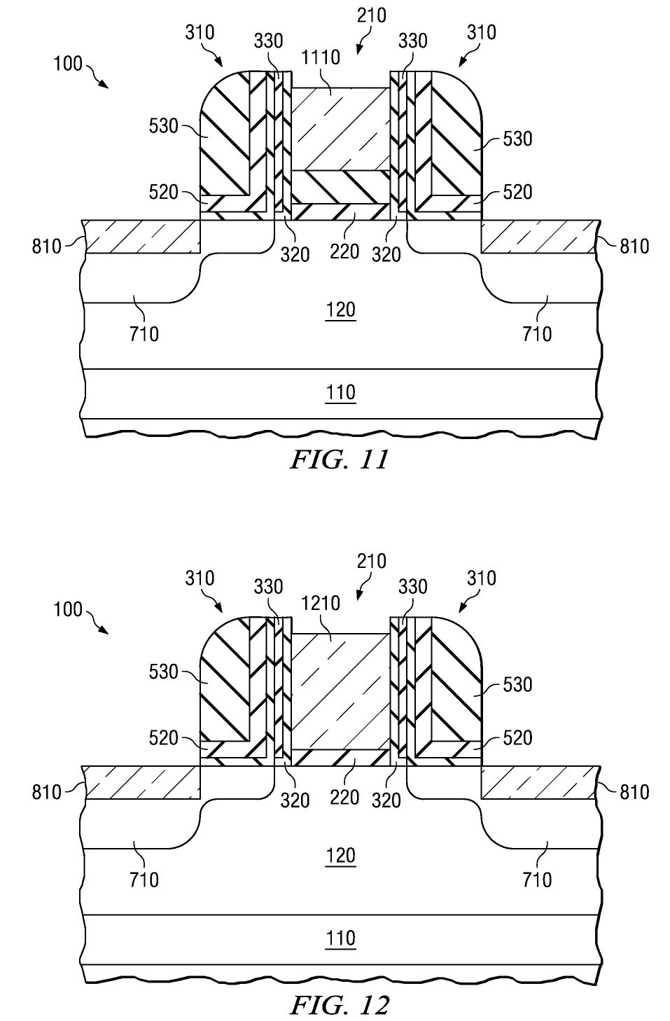

FIG. 11 illustrates the device 100 of FIG. 10 after subjecting the gate electrode 230 and metal 1010 to a silicidation process, thus forming a silicided gate electrode 1110. The resulting silicided gate electrode 1110, in the example embodiment shown, is not fully silicided. However, other embodiments may exist wherein it is fully silicided. Therefore, in the embodiment of FIG. 11, unreacted polysilicon remains therein. The silicided gate electrode 1110 includes the selected metal, in this embodiment nickel. If the metal 1010 were to comprise a different metal or alloy, the silicided gate electrode 1110 would comprise different elements.

Those skilled in the art understand the silicidation process, including subjecting the gate electrode 230 and metal layer 1010 to another anneal (e.g., a third anneal within a furnace). This third anneal is designed to convert the gate electrode 230 to the silicided gate electrode 1110. Advantageous to the disclosure, the selection and use of a lower temperature anneal reduces (if not eliminates) the formation of undesirable transient phases, and thus reduces (if not eliminates) the aforementioned transient stress. For example, the maximum temperature of this third anneal should not exceed about 340° C. In one embodiment wherein nickel is the metal, the third anneal may be conducted at a maximum temperature not to exceed about 300° C. It is believed that the aforementioned lower temperatures meet the activation energy required for stress relaxation, but are not sufficient to meet the activation energy required for certain phase transformations. The amount of time required for the third anneal will be based upon the amount of time required to silicidize the gate electrode 230.

After completing the silicided gate electrode 1110, the device 100 may be subjected to a selective removal process. For instance, in one embodiment the device 100 could be subjected to an etch recipe consisting of sulfuric acid (H₂SO₄), hydrogen peroxide (H₂O₂) and water (H₂O). This specific etch recipe has a high degree of selectivity and could easily remove any remaining portions of the metal 1010 without harming the silicided gate electrode 1110.

FIG. 12 illustrates the device 100 of FIG. 11 after subjecting the silicided gate electrode 1110 to an additional anneal (e.g., a fourth anneal in this embodiment) to form a fully silicided gate electrode 1210. The term “fully silicided”, as used throughout this disclosure, means that all of the silicon within the gate electrode has reacted to form a metal silicide. The fully silicided gate electrode 1210 comprises a different phase of the metal silicide than the silicided gate electrode 1110.

Those skilled in the art understand this fourth anneal process. Nevertheless, in one embodiment this fourth anneal may be conducted at a higher temperature, for example using a maximum temperature exceeding about 400° C. In one embodiment, the fourth anneal temperature ranges from about 400° C. to about 650° C. and is conducted for a time period ranging from about 10 second to about 100 seconds. It should be noted that other temperatures, times, and processes could be used. After completing the fourth anneal, the manufacture of the device 100 would typically continue in a conventional manner.

It should be noted that the method for manufacturing a semiconductor device as illustrated in FIGS. 1-12 represents only one embodiment of the present disclosure. In another embodiment the exact order of the steps illustrated with respect to FIGS. 1-12 might change depending on the process flow. In yet another embodiment, various other steps could be added to the description of FIGS. 1-12. Other more significant modifications to the process of FIGS. 1-12 also exist. For instance, other embodiments exist where the silicided source/drain regions 810 are not formed until after siliciding the gate electrode 230 to form the silicided gate electrodes 1110, 1210. Those skilled in the art understand the steps that could be used to accomplish this, as well as the steps used to accomplish other variations of that which is currently claimed.

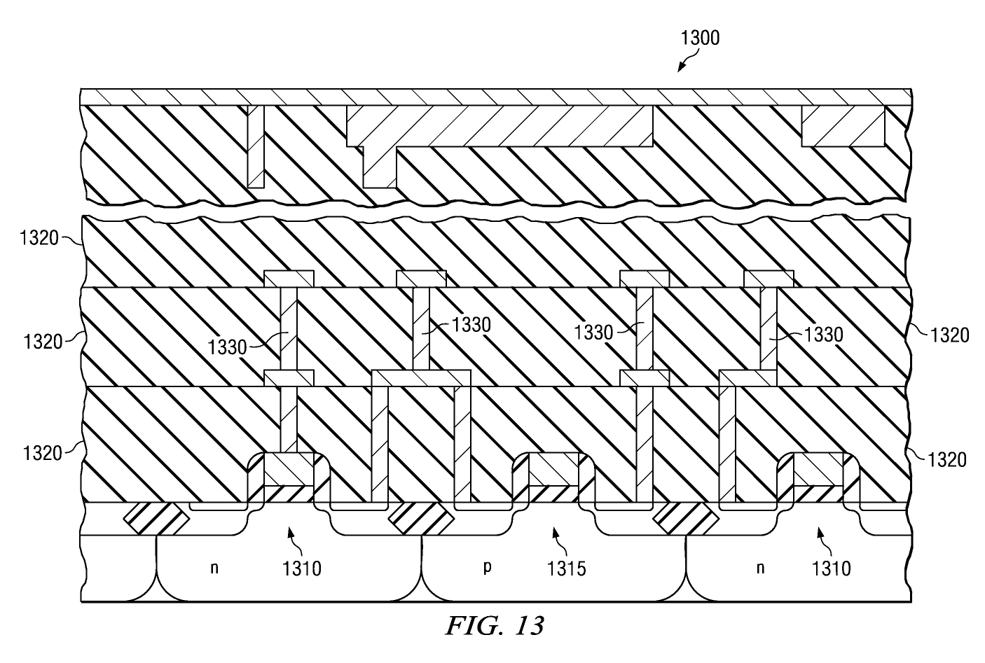

FIG. 13 illustrates an integrated circuit (IC) 1300 having been manufactured using one embodiment of the disclosure. The IC 1300 may include devices, such as transistors used to form CMOS devices, BiCMOS devices, Bipolar devices, as well as capacitors or other types of devices. The IC 1300 may further include passive devices, such as inductors or resistors, or it may also include optical devices or optoelectronic devices. Those skilled in the art are familiar with these various types of devices and their manufacture. In the particular embodiment illustrated in FIG. 13, the IC 1300 includes NMOS devices 1310 and PMOS devices 1315. For instance, in one embodiment the NMOS devices 1310 and PMOS devices 1315 illustrated in FIG. 13 are manufactured using similar processes as described above with respect to FIGS. 1-12, and thus may both be manufactured using the lower temperature anneal. The NMOS devices 1310 and PMOS devices 1315, in the illustrated embodiments, each include gate structures having gate dielectrics and gate electrodes. The NMOS devices 1310 and PMOS devices 1315 further include source/drain regions. Located over the devices 1310, 1315 are interlevel dielectric layers 1320. Located within the interlevel dielectric layers 1320 and contacting the devices 1310, 1315 are interconnects 1330. The resulting IC 1300 is optimally configured as an operational integrated circuit.

Those skilled in the art to which the present disclosure relates will appreciate that other and further additions, deletions, substitutions and modifications may be made to the described embodiments without departing from the disclosure's scope.

What is claimed is:

1. A method for manufacturing a semiconductor device, comprising:
forming a gate structure over a substrate, wherein the gate structure includes a gate dielectric and a gate electrode;
forming a metal layer over the gate electrode; and
forming a fully silicided gate electrode using the metal layer, including:
subjecting the gate electrode to a first anneal in a presence of the metal layer to form a silicided gate electrode, wherein a maximum temperature of the first anneal does not exceed about 340° C.;
removing any unreacted portions of the metal layer after the first anneal; and
subjecting the silicided gate electrode to a second anneal to form the fully silicided gate electrode subsequent to the removing, wherein a maximum temperature of the second anneal exceeds about 400° C.

2. The method of claim 1 wherein a maximum temperature of the first anneal does not exceed about 300° C.

3. The method of claim 1 wherein forming the metal layer includes forming the metal layer in contact with the gate electrode.

4. The method of claim 1 further including forming source/drain regions in the substrate proximate the gate structure.

5. The method of claim 4 further including forming silicided source/drain regions within the source/drain regions.

6. The method of claim 5 wherein forming silicided source/drain regions occurs before forming the metal layer.

7. The method of claim 1 wherein annealing includes annealing using a furnace.

8. The method of claim 1 further including forming interlevel dielectric layers over the gate structure, wherein the interlevel dielectric layers include interconnects therein for contacting the gate structure.

9. A method for manufacturing a semiconductor device, comprising:
forming a gate structure over a substrate, wherein the gate structure includes a gate dielectric and a gate electrode;
forming a metal layer over the gate electrode; and
annealing the gate electrode in a presence of the metal layer to form a silicided gate electrode, wherein a maximum temperature of the annealing does not exceed about 340° C.

10. The method of claim 9 wherein a maximum temperature of the annealing does not exceed about 300° C.

11. A method for manufacturing a semiconductor device, comprising:
forming a substrate having a p-type metal oxide semiconductor (PMOS) device region and n-type metal oxide semiconductor (NMOS) device region;
forming a first gate structure comprising a first gate dielectric and a first gate electrode over the substrate in the PMOS device region;
forming a second gate structure comprising a second gate dielectric and a second gate electrode over the substrate in the NMOS device region;
forming first source/drain regions in the substrate proximate the first gate structure;
forming second source/drain regions in the substrate proximate the second gate structure;
forming a metal layer in contact with the first gate electrode and the second gate electrode; and
annealing the first gate electrode and the second gate electrode in a presence of the metal layer to form a first silicided gate electrode and a second silicided gate electrode, wherein a maximum temperature of the annealing does not exceed about 340° C.

12. The method of claim 11 wherein a maximum temperature of the annealing does not exceed about 300° C.

13. The method of claim 11 wherein annealing includes subjecting the first gate electrode and the second gate electrode to a first anneal, and further including removing any unreacted portions of the metal layer after the first anneal, and then subjecting the first silicided gate electrode and second silicided gate electrode to a second anneal, thereby forming a first fully silicided gate electrode and a second fully silicided gate electrode.

14. The method of claim 13 wherein a maximum temperature of the second anneal exceeds about 400° C.

15. The method of claim 11 further including forming first silicided source/drain regions within the first source/drain regions and second silicided source/drain regions within the second source/drain regions.

16. The method of claim 15 wherein forming first and second silicided source/drain regions occurs before forming the metal layer.

17. The method of claim 11 wherein annealing includes annealing using a furnace.

18. The method of claim 11 further including forming interlevel dielectric layers over the first and second gate structures, wherein the interlevel dielectric layers include interconnects therein for contacting the gate structure.

19. A method for manufacturing a semiconductor device, comprising:
selecting a maximum silicidation temperature based upon a desire to exclude a predetermined silicidation transient phase of a gate electrode material;
forming a gate structure over a substrate, wherein the gate structure includes a gate dielectric and a gate electrode including the gate electrode material;
forming a metal layer over the gate electrode; and
annealing the gate electrode using the selected maximum silicidation temperature in a presence of the metal layer to form a silicided gate electrode.

20. The method of claim 19 wherein selecting includes selecting to reduce the formation of Ni₃₁Si₁₂.

21. The method of claim 19 wherein annealing the gate electrode includes subjecting the gate electrode to a first anneal, and further including removing any unreacted portions of the metal layer after the first anneal, and subjecting the silicided gate electrode to a second anneal subsequent to the removing, thereby forming a fully silicided gate electrode.
